(19) United States
(12) Patent Application Publication
(10) Pub. No.: US 2006/0071679 A1
(43) Pub. Date: Apr. 6, 2006

(54) System and method for the probing of a wafer

(75) Inventors: Byron H. Gibbs, McKinney, TX (US); Adolphus E. McClanahan, Garland, TX (US); Phillip H. Ball, Richardson, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 10/958,777

(22) Filed: Oct. 4, 2004

(51) Int. Cl. G01R 31/26

(52) U.S. Cl. 324/765

(57) ABSTRACT

According to one embodiment of the invention, a method for probing a wafer includes positioning a testhead relative to a prober supporting a wafer in a testing position. The method also includes receiving at least one prober signal identifying the angular position of the prober and at least one testhead signal identifying the angular position of the testhead. The at least one prober signal and the at least one testhead signal are processed to determine if the testhead is substantially parallel with the prober, and output is provided to allow for adjustment of the position of the testhead in response to determining that the testhead is not substantially parallel with the prober.

### TECHNICAL FIELD OF THE INVENTION

This invention relates in general to the testing of electronic components, and more particularly to a system and method for the probing of a wafer.

### BACKGROUND OF THE INVENTION

An array of die, which may include integrated circuits and their components, are typically supported on a wafer during various semiconductor fabrication processes. At various stages during fabrication processes, it may be desirable to perform testing on each die to read information from each die, write information to each die, or otherwise gather information about each die and components on each die. During testing, the wafer is typically loaded into a prober that operates to sequentially align each die on the wafer with the test equipment. To perform testing on each die of the wafer, the test equipment typically includes a testhead that is positioned and locked proximate the prober in an optimum testing position. This positioning and locking operation is known as “docking” the testhead to the prober. For example, where the test environment includes a mounted probe card, the testhead is to be docked into position such that one or more contact points of the die can be aligned with one or more contact points on the probe card.

Typical manipulating and docking systems do not compensate for stack up variances associated with component interchangeability within the testhead, probe card and prober. Rather, they rely on stack up tolerance control to ensure that the plane formed by the probe card's contact points is parallel to the plane of the die's contact points. Achieving and maintaining parallelism of these two planes by stack up control alone is impractical for systems that use vacuum to attach the probe card to the testhead. Planarity in vacuum attach systems is particularly vulnerable to stack up errors since the probe card's contact reference plane is primarily influenced by the reference plane of the testhead, its interfacing components, the prober, and the physical characteristics of the probe card itself.

### SUMMARY OF THE INVENTION

From the foregoing it may be appreciated by those skilled in the art that a need has arisen for a system and method for the probing of a wafer. In accordance with the present invention, a system and method for the probing of a wafer is provided that substantially eliminates or greatly reduces disadvantages and problems associated with conventional wafer test equipment.

In one embodiment, a method for probing a wafer includes positioning a testhead relative to a prober supporting a wafer in a testing position. The method also includes receiving at least one prober signal identifying the angular position of the prober and at least one testhead signal identifying the angular position of the testhead. The at least one prober signal and the at least one testhead signal are processed to determine if the testhead is substantially parallel with the prober, and output is provided to allow for adjustment of the position of the testhead in response to determining that the testhead is not substantially parallel with the prober.

Depending on the specific features implemented, particular embodiments of the present invention may exhibit some, none or all of the following technical advantages. Various embodiments may be capable of determining whether components of a testing system are substantially parallel with components of a probing system. For example, the angular alignment of a testhead with respect to a prober may be determined. One embodiment may be capable of ensuring the accurate and precise angular positioning of the testhead relative to the prober and the wafer. Thus, contact between the test equipment and the wafer may be substantially improved and the information from the wafer more accurately obtained during the subsequent probing session. In addition to improving the parallelism of the testhead relative to the prober prior to the initiation of a probing session, one embodiment may be capable of ensuring that the testhead remains substantially parallel with the prober throughout the entire probing session. Accordingly, the angular position of the testhead relative to the prober may be continuously or periodically monitored. As a result, the detection of an angular misalignment may be quickly detected, the probing session suspended, and the misalignment remedied.

Other technical advantages will be readily apparent to one skilled in the art from the following figures, descriptions, and claims.

### BRIEF DESCRIPTION OF THE DRAWINGS

For a more complete understanding of the invention and the advantages thereof, reference is now made to the following description, taken in conjunction with the accompanying drawings, wherein like reference numerals represent like parts, in which:

FIG. 1 is a block diagram of a system for the probing of a wafer;

FIG. 2 is a block diagram of a sensor analyzer for improving the alignment of components of a probing system; and

FIG. 3 is a flowchart of a method for the probing of a wafer after one or more partial probing sessions have been aborted.

### DETAILED DESCRIPTION OF EXAMPLE EMBODIMENTS OF THE INVENTION

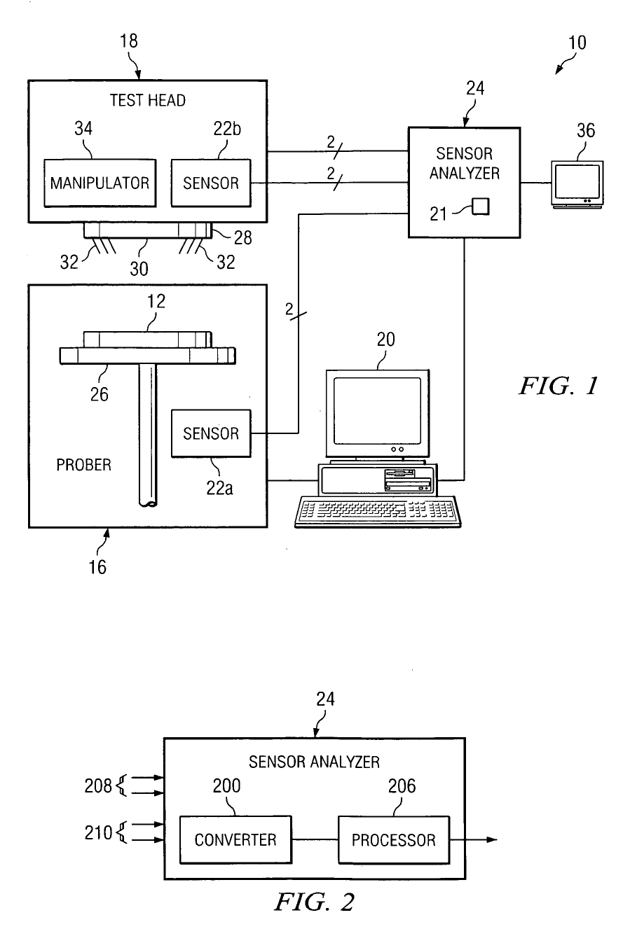

FIG. 1 is a block diagram of a system 10 for the probing of a wafer 12. In various embodiments, wafer 12 may include a thin polished slice of crystal material sliced from a crystal cylinder grown for the purpose of semiconductor fabrication. In a typical fabrication technology, a wafer provides the foundation on which a semiconductor device may be created. The semiconductor device may be created on the surface of the wafer using a variety of techniques and procedures, such as layering, photolithographic patterning, doping through implantation of ionic impurities, and heating. The starting material may comprise silicon, gallium arsenide, or other suitable substrate material. As will be described in further detail below, system 10 includes a prober 16, a testhead 18, and a controller 20. In particular embodiments, the different components of system 10 cooperate to read data from, write data to, or otherwise gather information about each die on wafer 12. For the efficient and accurate performance of these functions, testhead 18 and prober 16 each include a sensor system 22 for detecting the angular alignment of various components within system 10. A sensor analyzer 24 receives angular position information associated with the components and determines whether testhead 18 is in an optimum testing angular position relative to prober 16 and wafer 12. In specific embodiments, sensor system 22 may be able to detect the parallelism of testhead 18 relative to prober 16.

Prior to the probing process, system 10 includes a transfer assembly (not shown) or other apparatus for mechanically or robotically moving wafer 12 from one component to another component in system 10. For example, the transfer assembly may transport wafer 12 to prober 16 from a storage module or other component of system 10 or another fabrication system. Prober 16 includes a chuck 26 on which wafer 12 may be placed by the transfer assembly. Chuck 26 includes a supportive structure that may be mechanically or robotically operated to move horizontally and vertically within prober 16. A vacuum or other force may be applied to wafer 12 through chuck 26 to hold wafer 12 on chuck 26 while wafer 12 is in prober 16. In operation, chuck 26 may be mechanically or robotically moved to position wafer 12 into a testing position such that data may be retrieved from or imported to wafer 12. More specifically, chuck 26 may be moved horizontally and vertically to sequentially position each die on wafer 12 in the testing position.

In the testing position, wafer 12 is positioned beneath a probe card 28 that includes circuitry and components enabling probe card 28 to operate as an interface between wafer 12 and testhead 18. In the illustrated embodiment, probe card 28 is suspended from testhead 18 and, thus, forms a component associated with and manipulated by testhead 18. In other embodiments, however, probe card 28 may be at a fixed location within prober 16. Regardless of whether probe card 28 is a component of testhead 18 or prober 16, wafer 12 may be positioned such that during the testing process a particular die on wafer 12 is aligned with or positioned proximate to probe card 28. In particular embodiments, one or more pins 32 may extend from the lower or bottom surface of probe card 28. For example, pins 32 may extend from an edge of an aperture 30 of probe card 28. In the testing position, each pin 32 contacts an associated pad or contact point on the particular die being tested. At any one time during probing, pins 32 make contact with pads or contact points associated with a particular die on wafer 12 that is undergoing testing. Accordingly, pins 32 of probe card 28 operate as an interface between probe card 28 and the particular die on wafer 12 undergoing testing. Although probe card 28 is described as comprising a substantially round component that includes an aperture 30 configured through the probe card 28, the configuration of probe card 28 may be dependent upon the particular type of wafer 12 undergoing probing. As a result, it is generally recognized that probe card 28 may be of any appropriate size, shape, and configuration for providing an interface between each die supported on wafer 12 and the components of testhead 18.

Pins 32 allow testhead 18 to test each die supported on wafer 12. Thus, testhead 18 may be used to read data from, write data to, and/or otherwise gather information about each die on wafer 12. For example, testhead 18 may perform a functional test to determine whether each die is operating correctly. As discussed above, wafer 12 is in the proper testing position when pads or contact points on wafer 12 can be positioned to contact their respective pins 32 on the probe card 28 within the required limits.

Testhead 18 may include an electronically controlled and actuated manipulator 34. Manipulator 34 may include appropriate circuitry and software for allowing testhead 18 to be accurately manipulated with respect to at least three spatial axes for the alignment of testhead 18 to prober 16. In particular embodiments, manipulator 34 may include a docking system for positioning and locking testhead 18 to prober 16. In the optimal testing position, testhead 18 is substantially parallel to prober 16. For purposes of this document, substantially parallel includes deviations within a range determined and specified by user needs. Thus, testhead 18 is properly aligned with prober 16 when the surface of testhead 18, as measured by a sensor, is parallel to a surface of prober 16, as measured by a sensor, within a range determined and specified by user needs. During a probing session, the parallelism of testhead 18 and prober 16 may be periodically or continuously monitored and compared against benchmark angular positions of testhead 18 and prober 16. The parallelism of testhead 18 relative to prober 16 may also be verified after a suspension of a probing session, after the interchanging or substitution of components within system 10, or after undocking and redocking testhead 18 to prober 16 as these events may result in the angular misalignment of testhead 18 relative to prober 16. As will be described in more detail below, where the angular misalignment of testhead 18 is detected, manipulator 34 and/or the docking system may be used to realign testhead 18 with respect to prober 16.

As discussed above, the parallelism of testhead 18 and prober 16 may be compared against benchmark positions of testhead 18 and prober 16. As one example for the setting of the benchmark positions, a user may initiate a calibration session whereby the user may use a reference probe card and procedure to determine error components associated with the parallelism of testhead 18 relative to prober 16. During the calibration session, the user may adjust the position of testhead 18 to improve the parallelism of testhead 18 relative to prober 16. As will be described in more detail below, system 10 may include one or more displays on which the position of testhead 18 and prober 16 may be communicated to a user. Using one or more of these displays, the parallelism of testhead 18 and prober 16 relative to one another may be displayed to the user performing the test probing session. When the user determines that testhead 18 and prober 16 are substantially parallel, the user may set the angular positions of testhead 18 and prober 16 as benchmark positions which will act as reference points by which the angular positions of testhead 18 and prober 16 should be measured during probing. For example, the user may set the benchmark angular positions by pushing a button 21 on sensor analyzer 24. However, although button 21 is illustrated as a component of sensor analyzer 24, it is recognized that button 21 need not be placed on sensor analyzer 24 and could be placed on any other component within system 10 that communicates with sensor analyzer 24. For example, button 21 may be placed on testhead 18 or on prober 16. As still another example, it is also recognized that button 21 may be unnecessary where a user is permitted to indicate that the benchmark positions of testhead 18 and prober 16 should be set using controller 20. For example, where controller 20 includes a computer or other processor, a user may set the benchmark positions using a keyboard, mouse, or other input device.

System 10 also includes controller 20 that communicates with one or more components of system 10. In the illustrated embodiment, controller 20 communicates with prober 16. In particular embodiments, controller 20 may control or drive the operations of prober 16. Accordingly, controller 20 may include the software necessary to generate and communicate commands to prober 16. The commands communicated to prober 16 may direct prober 16 to begin a probing session, stop a probing session, or resume a probing session. In particular embodiments, controller 20 may generate these and other commands and communicate the commands directly or indirectly through other systems to prober 16 when an angular misalignment of testhead 18 relative to prober 16 is detected. For example, controller 20 may direct prober 16 to suspend a probing session when an angular misalignment of testhead 18 relative to prober 16 is detected. Similarly, controller 20 may direct prober 16 to resume a probing session when the misalignment of testhead 18 is remedied. Because the commands driving prober 16 are originated at controller 20, at least a portion of the operations performed by prober 16 are controlled externally from prober 16.

In the illustrated embodiment, prober 16 and testhead 18 each include a sensor system 22. Specifically, prober 16 includes a sensor system 22a, and testhead 18 includes a sensor system 22b. Sensor systems 22 may be mounted on or otherwise incorporated into the test equipment. Each sensor system 22 includes an x-axis sensor and a y-axis sensor. The x- and y-axis sensors operate to obtain angular position information about the component on which the sensor system 22 is mounted relative to an x-y plane. Thus, sensor system 22a obtains angular position information associated with prober 16. Sensor system 22b obtains angular position information associated with testhead 18. The position information may identify the planar position of the respective device relative to a benchmark position. As discussed above, the benchmark position may include the angular position of testhead 18 relative to prober 16 when it is verified that the testhead 18, through probecard 28, properly interfaces with a die on wafer 12.

In particular embodiments, sensor systems 22 may each include an EZtilt 3000 level sensor as manufactured by Advanced Orientation Systems, Inc. In such leveling systems, the x- and y-axis sensors of sensor systems 22 may provide angular position information as a measure of impedance, which includes dual axis angle measurements as analog outputs. For example, each sensor system 22 may output two analog signals. In particular embodiments, each signal may include voltages proportionally scaled between 0 and 5 millivolts. The signals may be used to identify the angular positions of the devices on which the sensors are mounted relative to the benchmark position. The EZtilt 3000 level sensor is just one example, however, of leveling systems that may be used as sensor systems 22. Any sensor for detecting or identifying the angular position of an object may be used. Accordingly, although position information is described as including an impedance measurement, it is recognized that position information may include any appropriate information for identifying the position of the device. For example, in alternative embodiments, the position information may include a set of coordinates relative to a reference system or other position identifier.

The signals generated by each sensor system 22 may be communicated to sensor analyzer 24. Sensor analyzer 24 is discussed in more detail with regard to FIG. 2. In various embodiments, however, sensor analyzer 24 may be configured to receive and process the signals generated by sensor systems 22a and 22b. In particular embodiments, the processing of the signals may include the conversion of the analog signals into digital signals. The digital signals may represent x- and y-angular coordinates or other position identifiers. The position coordinates associated with testhead 18 and prober 16 may then be compared to a benchmark, which may be set prior to the probing session using button 21 in particular embodiments, to determine if testhead 18 is in proper alignment with prober 16. As discussed above, the alignment of testhead 18 is proper when testhead 18 is substantially parallel to prober 16. In particular embodiments, testhead 18 may be in proper alignment when the composite plane created by contact points or pins 32 of probe card 28 is substantially parallel to the pads or contact points of wafer 12. Where the alignment of testhead 18 is determined to be improper, sensor analyzer 24 may communicate signals, commands, or angular position information to manipulator 34 to result in the termination of the testing process or the adjustment of testhead 18 to place testhead 18 in the proper testing position. The provision of such signals, commands, or position information from sensor analyzer 24 to manipulator 34 and/or the docking system may close a feed back loop. For the processing of conflicting or otherwise incompatible information, manipulator 34, the docking system, and/or sensor analyzer 24 may include circuitry suitable for stabilizing the feed back loop.

In particular embodiments, sensor analyzer 24 may communicate the signals, coordinates, or other position information to a display 36. Display 36 includes the circuitry to receive the signals, coordinates, or other position information, convert the position information into a displayable format, where appropriate, and display the position information to a user. For example, display 36 may include a display screen, such as an LCD screen or other visual display technologies to display the angular coordinates to the user. The sets of coordinates corresponding to testhead 18 and prober 16 may be displayed to the user simultaneously or in succession. Additionally or alternatively, the difference between the two sets of coordinates may be displayed to the user. The position information may be noted, recorded, or otherwise archived by the user. In certain embodiments, the information may enable the user to perform rough or fine adjustments of testhead 18 by mechanically repositioning testhead 18. Alternatively, the user may issue one or more commands to manipulator 34 and/or the docking system of testhead 18 to cause the adjustment in position of testhead 18. The mechanical adjustment of testhead 18 by the user may be in addition to or in lieu of the adjustment of the testhead 18 by manipulator 34.

As illustrated in FIG. 1, display 36 is a component associated with but external to sensor analyzer 24. It is recognized, however, that display 36 may be incorporated into sensor analyzer 24 or any other component of system 10. For example, display 36 may be a component of testhead 18 or prober 16, and the appropriate circuitry may be provided between display 36 and sensors 22 for the displaying of position information to a user. In still other embodiments, display 36 may be a component of controller 20, and sensor analyzer 24 may provide the position information to controller 20. Controller 20 may then display the position information to the user on a graphical user interface screen associated with controller 20. For example, where controller 20 comprises a computing device, the position information may be communicated to controller 20 and displayed on the computer's monitor.

Although an example system 10 is illustrated and described, the configuration of system 10 is provided as one example of a system for the alignment of testing components for the probing of wafer 12. Accordingly, the present invention contemplates any configuration appropriate for the external driving and manipulation of probing and test equipment. Thus, system 10 may include fewer or more components than those depicted in FIG. 1. For example, although system 10 is described as including controller 20 and sensor analyzer 24, it is recognized that the functionalities described for controller 20 and sensor analyzer 24 may be combined in a single component. Accordingly, either sensor analyzer 24, controller 20, or both may be omitted from system 10. Additionally, any of the described modules or components may be external to system 10 and the test equipment. Thus, where system 10 does not include controller 20 or sensor analyzer 24, a component external to the illustrated system 10 may perform the functionalities described above for controller 20 and sensor analyzer 24. Further, although illustrated as a component of controller 20, relational database 50 may be external to system 10 and/or may be accessible to other systems.

FIG. 2 is a block diagram of sensor analyzer 24 for improving the alignment of components of system 10. Sensor analyzer 24 includes a converter 200 and a processor 202. In particular embodiments, sensor analyzer 24 receives angular position information from testhead 18 and prober 16. As discussed above, the position information may comprise signals representing the planar positions of testhead 18 and prober 16. Sensor analyzer 24 may use the signals to detect, display, and/or remedy the angular misalignment of testhead 18 relative to prober 16.

In particular embodiments, sensor analyzer 24 receives a first set of signals 208 and a second set of signals 210. First set of signals 208 represent the position of prober 16 as measured by the x- and y-axis sensors, respectively, of sensor system 22a. Similarly, second set of signals 210 represent the angular position of testhead 18 as measured by the x- and y-axis sensors, respectively, of sensor system 22b. In particular embodiments, and as described above, each signal in first and second sets of signals 208 and 210 are analog signals derived from changes in impedance identifying changes in the angular positions of testhead 18 and prober 16 with respect to benchmark position. Converter 200 receives first and second sets of signals 208 and 210 and includes the analog circuitry required to convert each of the signals into an offset. Specifically, converter 200 receives first set of signals 208 from prober 16 and converts first set of signals 208 into an x-axis offset and a y-axis offset, which provide offset measurements associated with prober 16 about the x-axis and the y-axis. Similarly, converter 200 receives second set of signals 210 from testhead 18 and converts second set of signals 210 into an x-offset and a y-offset, which provide offset measurements associated with testhead 18 about the x-axis and the y-axis. Accordingly, the current positions of testhead 18 and prober 16 may be determined with respect to two axes. In other embodiments, additional signals may be received such that the positions of testhead 18 and prober 16 may be determined with respect to more than two axes.

The offsets may be communicated to a processor 206, which includes digital circuitry and software for analyzing the offsets. Specifically, processor 206 analyzes the angular offsets to determine whether testhead 18 is misaligned relative to prober 16. For example, processor 206 may compare the x-axis offset associated with prober 16 with the x-axis offset associated with testhead 18. Processor 206 may also compare the y-axis offset associated with prober 16 with the y-axis offset associated with testhead 18. The comparisons may enable processor 206 to determine if testhead 18 is properly aligned with prober 16. For example, where the x-axis offset associated with prober 16 is proximate to the x-axis offset associated with testhead 18 and where the y-axis offset associated with prober 16 is proximate to the y-axis offset associated with testhead 18, processor 206 may determine that testhead 18 is properly aligned. Conversely, where either the x-axis offset associated with prober 16 does not match the x-axis offset associated with testhead 18 or the y-axis offset associated with prober 16 does not match the y-axis offset associated with testhead 18, processor 206 may determine that testhead 18 is angularly misaligned.

In other embodiments, processor 206 may compare the offsets associated with testhead 18 and prober 16 to benchmark angular positions associated with testhead 18 and prober 16. For example, processor 206 may compare the x-axis offset associated with prober 16 with a benchmark x-axis value associated with prober 16. Similarly, the y-axis offset associated with prober 16 may be compared with a benchmark y-axis value associated with prober 16. Where the comparisons determine that the values do not match, processor 206 may deduce that the angular position of prober 16 has changed from the benchmark angular position. A similar comparison may be performed to determine if the angular position of testhead 18 has changed from the benchmark angular position.

In various embodiments, processor 206 also generates one or more commands in response to the determination as to whether testhead 18 is misaligned. In particular embodiments, processor 206 may generate a command and communicate that command to manipulator 34 and/or the docking system of testhead 18. The command may direct manipulator 34 and/or the docking system to adjust the position of testhead 18 relative to prober 16. In particular embodiments, the issued command may include an ASCII phrase that directs manipulator 34 and/or the docking system to adjust the position of testhead 18. In other embodiments, the command may include position information in digital or analog form that may be used by manipulator 34 and/or the docking system to determine the amount and direction of the adjustment required for properly aligning testhead 18 with prober 16.

In particular embodiments, processor 206 may also communicate one or more commands to controller 20. In particular embodiments, the issued command may include an ASCII phrase that indicates the angular misalignment of testhead 18 to controller 20. For example, where processor 206 detects a misalignment of testhead 18 while a probing session is underway, the one or more commands communicated to controller 20 may direct controller 20 to suspend the probing session. Alternatively, where processor 206 detects a misalignment of testhead 18 before a probing session is initiated, the one or more commands may direct controller 20 not to initiate the probing session until the misalignment is remedied. In still other embodiments, processor 206 may merely provide the coordinates and/or position information to controller 20. Controller 20 may then analyze the information received to determine whether a probing session should be initiated, suspended, or resumed.

Although an example sensor analyzer 24 is illustrated and described in FIG. 2, the configuration of sensor analyzer 24 is provided as one example of a system for checking the alignment of testing components for the probing of wafer 12. Accordingly, the present invention contemplates any configuration appropriate, and sensor analyzer 24 may include fewer or more component than those depicted in FIG. 2. For example, although sensor analyzer 24 is described as including converter 200 for the conversion of analog signals into digital signals, it is recognized that in some embodiments such conversion may be unnecessary. Where, for example, processor 206 includes the analog circuitry necessary to sense and compare different analog signals, converter 200 may be omitted from sensor analyzer 24. Furthermore, it is generally recognized that the functionalities described as pertaining to converter 200 and processor 206 may be performed by a single component within sensor analyzer 24 or by a component external to sensor analyzer 24 and/or system 10.

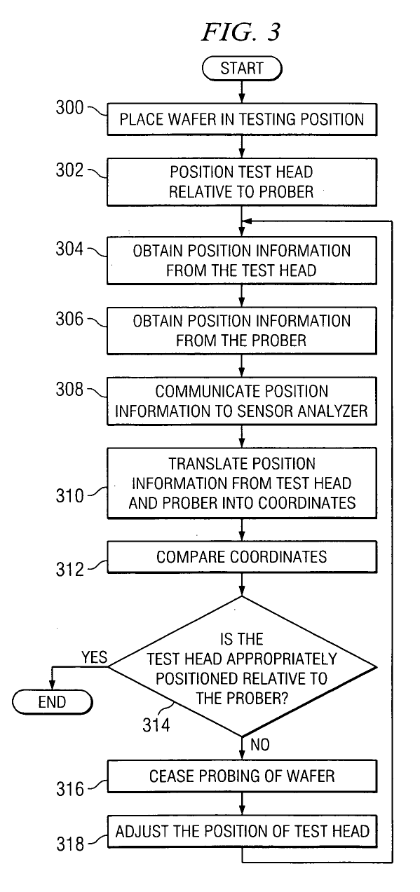

FIG. 3 is a flowchart of a method for probing a wafer 12, and especially for the alignment of test equipment components. Depending upon the particular implementation of system 10, the method described may begin prior to the initiation of a probing session or at some point while the probing session is in progress. Accordingly, the alignment of the components of system 10 may be assessed prior to a probing session and then, additionally or alternatively, monitored throughout the probing session.

At step 300, wafer 12 is placed in the testing position. In particular embodiments, wafer 12 may be mechanically or robotically placed on chuck 26. A vacuum or other force may be applied to wafer 12 through chuck 26 to hold wafer 12 on chuck 26. During a probing session of wafer 12, chuck 26 may be mechanically or robotically moved to place wafer 12 in a position such that data may be retrieved from or imported to wafer 12. Testhead 18 is positioned relative to prober 16 and wafer 12 at step 302. Specifically, testhead 18 may be positioned so that probe card 28, which is suspended from testhead 18 or otherwise located between testhead 18 and prober 16, is substantially aligned with wafer 12. For example, testhead 18 may be positioned to align a particular die on wafer 12 with one or more retractable pins 32 extending from probe card 28.

At step 304, position information is obtained from testhead 18. The position information may be obtained from a sensor system 22b mounted on testhead 18. In particular embodiments, a set of voltage signals 210 may be obtained from sensor system 22b. The set of signals 210 may include a first signal representing the position of testhead 18 with respect to an x-axis and a second signal representing the position of testhead 18 with respect to a y-axis. The x-axis and the y-axis may define the plane corresponding to the position of testhead 18 relative to a benchmark position. In a similar manner, a set of signals 208 may be obtained from a sensor system 22a associated with prober 16 at step 306. The set of signals 208 may represent the position of prober 16 with respect to an x-axis and a y-axis that together define the plane corresponding to the position of prober 16 with respect to a benchmark position.

The first and second sets of signals 208 and 210 obtained in steps 304 and 306 are communicated to a sensor analyzer at step 308. In particular embodiments, where the first and second sets of signals 208 and 210 are analog voltage signals, sensor analyzer 24 may convert the first and second sets of signals 208 and 210 received from testhead 18 and prober 16 into two sets of corresponding angular offsets at step 310. Where first and second set of signals 208 and 210 are received as analog signals, the converted offsets may comprise digital signals.

At step 312, the angular offsets associated with testhead 18 may be compared to the angular offsets associated with prober 16. Alternatively or additionally, the angular offsets associated with testhead 18 may be compared with benchmark angular position coordinates associated with prober 16. The described comparisons may be used by sensor analyzer 24 or another component in system 10 to determine whether testhead 18 is aligned with prober 16 at step 314. In particular embodiments, the coordinates may be compared to determine whether testhead 18 is substantially parallel to prober 16. For example, sensor analyzer 34 may determine that testhead 18 is substantially parallel to prober 16 where the surface of testhead 18, as measured by a sensor, is substantially parallel to a surface of prober 16, as measured by a sensor, within a range determined and specified by user needs. Where it is determined that testhead 18 is not substantially parallel with prober 16, the probing of wafer 12 may be ceased where appropriate or the misalignment may be noted and remedied before the probing of the next batch of wafers is initiated. Accordingly, sensor analyzer 24 may communicate the analog signals, the converted offsets, and/or a command to controller 20 to identify to controller 20 that the probing of wafer 12 should be suspended where such probing is underway.

Before the probing session may be continued, the angular position of testhead 18 may be adjusted at step 318. In particular embodiments, sensor analyzer 24 may communicate the analog signals, the converted offsets, and/or a command to manipulator 34 and/or the docking system of testhead 18. Manipulator 34 and/or the docking system may then adjust the position of testhead 18 relative to prober 16 and wafer 12. After the adjustment of testhead 18, the probing session of wafer 12 may be initiated or resumed, as is appropriate, and the method may terminate. Alternatively, the method may return to steps 304 and 306 where position information is obtained from testhead 18 and prober 16. Thus, the method may cycle through steps 304-318 until testhead 18 is substantially parallel with prober 16. Accordingly, the angular position of testhead 18 relative to prober 16 may be iteratively adjusted until the proper angular alignment is obtained, upon which time the method may terminate.

In summary, a system and method for obtaining alignment of test equipment components for the probing of a wafer 12 is provided. The system and method include sensor systems 22 that are associated with testhead 18 and prober 16. The sensors provide position information to a sensor analyzer 34, which then operates to ensure the accurate and precise positioning of testhead 18 relative to prober 16 and wafer 12. In addition to improving the parallelism of testhead 18 relative to prober 16 prior to the initiation of a probing session, system 10 may further ensure that testhead 18 remains in substantially parallel with prober 16 throughout the entire probing session. For example, the angular position of testhead 18 relative to prober 16 may be continuously or periodically monitored to quickly determine if testhead 18 becomes misaligned. As a result, contact between testhead 18 and wafer 12 may be substantially improved and the information from wafer 12 more accurately obtained during the probing session.

Although embodiments of the invention and their advantages are described in detail, a person skilled in the art could make various alterations, additions, and omissions without departing from the spirit and scope of the present invention, as defined by the appended claims.

What is claimed is:

1. A method for probing a wafer comprising:
positioning a testhead relative to a prober supporting a wafer in a testing position;
receiving at least one prober signal identifying the angular position of the prober;
receiving at least one testhead signal identifying the angular position of the testhead;
processing the at least one prober signal and the at least one testhead signal to determine if the testhead is substantially parallel with the prober; and
providing output to allow for adjustment of the position of the testhead in response to determining that the testhead is not substantially parallel with the prober.

2. The method of claim 1, wherein:
receiving the at least one prober signal comprises;
receiving a first prober signal identifying the angular position of the prober about an x-axis; and
receiving a second prober signal identifying the angular position of the prober about a y-axis; and
receiving the at least one testhead signal comprises:
receiving a first testhead signal identifying the angular position of the testhead about the x-axis; and
receiving a second testhead signal identifying the angular position of the testhead about the y-axis.

3. The method of claim 2, wherein processing the first and second signals comprises:
comparing the first prober signal with the first testhead signal to determine if the first testhead signal is proximate to the first prober signal;
comparing the second prober signal with the second testhead signal to determine if the second testhead signal is proximate to the second prober signal; and
determining that an x-y plane associated with the testhead is not substantially parallel with an x-y plane associated with the prober where either comparison is found to be not proximate.

4. The method of claim 2, further comprising:
establishing a benchmark angular position for the prober and a benchmark angular position for the testhead; and
storing the benchmark angular position of the prober and the benchmark angular position of the testhead.

5. The method of claim 4, wherein processing the first and second signals comprises:
comparing the first prober signal to an x-axis value associated with the benchmark angular position of the prober;
comparing the second prober signal to a y-axis value associated with the benchmark angular position of the prober;
comparing a first testhead signal to an x-axis value associated with the benchmark position of the testhead;
comparing a second testhead signal to a y-axis value associated with the benchmark position of the testhead; and
determining that an x-y plane associated with the testhead is not substantially parallel with an x-y plane associated with the prober where any comparison is found to be not proximate.

6. The method of claim 1, wherein determining if the testhead is substantially parallel with the prober comprises determining if a probe card suspended from the testhead is substantially parallel with the wafer supported by the prober.

7. The method of claim 1, further comprising:
converting each of the at least one prober signals from an analog format to a digital format; and
converting each of the at least one testhead signals from an analog format to a digital format.

8. The method of claim 1, further comprising:
communicating a command to a controller of the prober in response to determining that the testhead is not substantially parallel with the prober, the command directing the prober to cease a probing session.

9. The method of claim 1, further comprising:
communicating with a manipulator to allow for automatic adjustment of the testhead to correct planarity errors when it is determined that the testhead is not substantially parallel with the prober.

10. The method of claim 1, further comprising:
displaying a misalignment indicator to a user in response to determining that the testhead is not substantially parallel with the prober.

11. A system for probing a wafer comprising:
a prober operable to support a wafer in a testing position;
a testhead positioned proximate the prober, the testhead comprising a manipulator operable to adjust the position of the testhead relative to the prober;
a sensor analyzer operable to:
receive at least one prober signal identifying the angular position of the prober;
receive at least one testhead signal identifying the angular position of the testhead;
process the at least one prober signal and the at least one testhead signal to determine if the testhead is substantially parallel with the prober; and
provide output to allow for adjustment of the position of the testhead in response to determining that the testhead is not substantially parallel with the prober.

12. The system of claim 11, wherein:
the at least one prober signal comprises;
a first prober signal identifying the angular position of the prober about an x-axis; and
a second prober signal identifying the angular position of the prober about a y-axis; and
the at least one testhead signal comprises:
a first testhead signal identifying the angular position of the testhead about the x-axis; and
a second testhead signal identifying the angular position of the testhead about the y-axis.

13. The system of claim 12, wherein when processing the at least one prober signal and the at least one testhead signal the sensor analyzer is operable to:
compare the first prober signal with the first testhead signal to determine if the first testhead signal is proximate to the first prober signal;
compare the second prober signal with the second testhead signal to determine if the second testhead signal is proximate to the second prober signal; and
determine that an x-y plane associated with the testhead is not substantially parallel with an x-y plane associated with the prober where either comparison identifies a mismatch in value.

14. The system of claim 12, wherein the sensor analyzer is further operable to:
establish a benchmark angular position for the prober and a benchmark angular position for the testhead; and
store the benchmark angular position of the prober and the benchmark angular position of the testhead.

15. The system of claim 14, wherein when processing the at least one prober signal and the at least one testhead signal the sensor analyzer is operable to:
compare the first prober signal to an x-axis value associated with the benchmark angular position of the prober;
compare the second prober signal to a y-axis value associated with the benchmark angular position of the prober;
compare a first testhead signal to an x-value associated with the benchmark angular position of the testhead;
compare a second testhead signal to a y-axis value associated with the benchmark angular position of the testhead; and
determine that an x-y plane associated with the testhead is not substantially parallel with an x-y plane associated with the prober where any comparison identifies a mismatch in value.

16. The system of claim 11, wherein the sensor analyzer is operable to determine if the testhead is substantially parallel with the prober by determining if a probe card suspended from the testhead is substantially parallel to the wafer supported by the prober.

17. The system of claim 11, wherein the sensor analyzer is further operable to:
communicate a command to a controller of the prober in response to determining that the testhead is not substantially parallel with the prober, the command directing the prober to cease a probing session.

18. The system of claim 11, wherein the sensor analyzer is further operable to:
communicate with a manipulator to allow for automatic adjustment of the testhead to correct planarity errors when it is determined that the testhead is not substantially parallel with the prober.

19. The system of claim 11, wherein the sensor analyzer is further operable to:
display an angular misalignment indicator to a user in response to determining that the testhead is not substantially parallel with the prober.

20. A system for probing a wafer comprising:
means for positioning a testhead relative to a prober supporting a wafer in a testing position;
means for receiving at least one prober signal identifying the angular position of the prober;
means for receiving at least one testhead signal identifying the angular position of the testhead;
means for processing the at least one prober signal and the at least one testhead signal to determine if the testhead is substantially parallel with the prober; and
means for providing output to allow for adjustment of the angular position of the testhead in response to determining that the testhead is not substantially parallel with the prober.
